(19) United States
(12) Patent Application Publication
(10) Pub. No.: US 2026/0105873 A1
(43) Pub. Date: Apr. 16, 2026

(54) OPTICAL COMPENSATION DEVICE, METHOD OF OPERATING THE SAME AND ELECTRONIC DEVICE

(71) Applicant: SAMSUNG DISPLAY CO., LTD., YONGIN-SI (KR)

(72) Inventor: Si Beak PYO, Yongin-si (KR)

(21) Appl. No.: 19/230,544

(22) Filed: Jun. 6, 2025

(30) Foreign Application Priority Data
Oct. 11, 2024 (KR) 10-2024-0138466

(51) Int. Cl. G09G 3/00; G09G 3/3233; H10K 59/121

(52) U.S. Cl. CPC G09G 3/006; G09G 3/3233; G09G 2300/0439; G09G 2320/0233; G09G 2320/0242; G09G 2360/14; H10K 59/121

(57) ABSTRACT

An optical compensation device includes a first sensor configured to measure light emitted from a first pixel area of a display device during a first time period, in response to a first test voltage, to generate a first light characteristic. An optical compensation device includes a first sensor configured to measure light emitted from the first pixel area during a second time period, in response to the first test voltage, to generate a third light characteristic. An optical compensation device includes a second sensor configured to measure light emitted from a second pixel area of the display device during the first time period, in response to a second test voltage, to generate a second light characteristic. An optical compensation device includes a test driver circuit configured to adjust the second test voltage, based on the first light characteristic and the second light characteristic.

### CROSS-REFERENCE TO RELATED APPLICATION

This application claims priority under 35 U.S.C. § 119 to Korean Patent Application No. 10-2024-0138466, filed on Oct. 11, 2024, in the Korean Intellectual Property Office, the disclosure of which is incorporated by reference herein in its entirety.

### Technical Field

The present disclosure relates to an optical compensation device, a method of operating the same, and an electronic device.

### Discussion of the Related Art

A display device may display an image using pixels, or using a pixel circuit. The display device may include a sensor, a camera, or the like on a bezel, or on an edge of a front surface of a display device. For example, the front surface may be a surface of the display device where an image is displayed. The display device may recognize an object using an optical sensor and may obtain a photo or a moving image using a camera.

A camera or the like may be located to overlap a pixel area to minimize the bezel. Resolution of a pixel area overlapping the camera may be less than the resolution of another pixel area of the display device not overlapping the camera.

### SUMMARY

According to embodiments of the disclosure, an optical compensation device includes a first sensor configured to measure light emitted from a first pixel area of a display device during a first time period, in response to a first test voltage, to generate a first light characteristic. An optical compensation device includes a first sensor configured to measure light emitted from the first pixel area during a second time period, in response to the first test voltage, to generate a third light characteristic. An optical compensation device includes a second sensor configured to measure light emitted from a second pixel area of the display device during the first time period, in response to a second test voltage, to generate a second light characteristic. An optical compensation device includes a test driver circuit configured to adjust the second test voltage, based on the first light characteristic and the second light characteristic.

In embodiments, the second sensor may be configured to measure light emitted from the second pixel area during a third time period, in response to the adjusted second test voltage, to generate an adjusted second light characteristic. The test driver circuit may be configured to output a third light characteristic generation request to the first sensor and output a fourth light characteristic generation request to the second sensor, when a difference between the adjusted second light characteristic and the first light characteristic is greater than or equal to a reference value. The first sensor may be configured to generate the third light characteristic, in response to the third light characteristic generation request. The third time period may be between the first time period and the second time period.

In embodiments, the test driver circuit may be configured to store the adjusted second test voltage in the display device, when the difference between the adjusted second light characteristic and the first light characteristic is less than or equal to the reference value.

In embodiments, in response to the fourth light characteristic generation request, the second sensor may be configured to measure light emitted from the second pixel area during the second time period, in response to the adjusted second test voltage, to generate a fourth light characteristic, and the test driver circuit may be configured to re-adjust the adjusted second test voltage, based on the third light characteristic and the fourth light characteristic.

In embodiments, a difference between the third light characteristic and the first light characteristic may include a difference in a luminance or a difference in a color coordinate of the light emitted from first pixels of the first pixel area over time from the first time period to the second time period.

In embodiments, the first light characteristic may be the luminance or the color coordinate of the light emitted from the first pixels during the first time period, in response to the first test voltage, the second light characteristic may be the luminance or the color coordinate of the light emitted from second pixels of the second pixel area during the first time period, in response to the second test voltage, the third light characteristic may be the luminance or the color coordinate of the light emitted from the first pixels during the second time period after the first time period, in response to the first test voltage, and the fourth light characteristic may be the luminance or the color coordinate of the light emitted from the second pixels during the second time period, in response to the adjusted second test voltage.

In embodiments, a number of the first pixels located per unit area may be greater than a number of the second pixels located per unit area.

According to embodiments of the disclosure, an electronic device includes a processor configured to generate input image data and a control signal, and a display device configured to display an image based on the input image data and the control signal. The display device includes a first pixel area including first pixels, and a second pixel area including second pixels. The display device is configured to communicate with an optical compensation device. The optical compensation device includes a first sensor configured to periodically measure light emitted from the first pixel area of the display device, in response to a first test voltage, to generate a first light characteristic. A most recently generated first light characteristic is stored as a target light characteristic. The optical compensation device includes a second sensor configured to measure light emitted from the second pixel area of the display device, in response to a second test voltage, to generate a second light characteristic. The optical compensation device includes a test driver circuit configured to adjust the second test voltage, based on the target light characteristic and the second light characteristic.

In embodiments, the second sensor may be configured to measure light emitted from the second pixel area, in response to the adjusted second test voltage, to generate an adjusted second light characteristic. The test driver circuit may be configured to output a light characteristic generation request to the second sensor and output a light transmission request to the first sensor, when a difference between the adjusted second light characteristic and the stored first light characteristic is greater than or equal to a reference value.

In embodiments, the test driver circuit may be configured to store the adjusted second test voltage in the display device, when the difference between the adjusted second light characteristic and the stored first light characteristic is less than or equal to the reference value.

In embodiments, the first sensor may be configured to output the target light characteristic to the test driver circuit, in response to the light transmission request. The second sensor may be configured to measure the light emitted from the second pixel area, in response to the adjusted second test voltage, to generate a third light characteristic. The third light characteristic maybe generated in response to the light characteristic generation request. The test driver circuit may be configured to re-adjust the adjusted second test voltage based on the target light characteristic and the third light characteristic.

In embodiments, the target light characteristic stored before receiving the light transmission request and the target light characteristic stored after receiving the light transmission request may be different from each other.

In embodiments, the difference between the target light characteristic stored before receiving the light transmission request and the target light characteristic stored after receiving the light transmission request may include a difference in a luminance or a difference in a color coordinate of light emitted from first pixels of the first pixel area over time.

According to embodiments of the disclosure, a method of operating an optical compensation device is disclosed. The optical compensation device is configured to communicate with a display device. The display device includes a first pixel area including first pixels, and a second pixel area including second pixels. The method of operating an optical compensation device includes adjusting a second test voltage based on a first light characteristic and a second light characteristic. The first light characteristic is generated during a first time period using the first pixels, in response to a first test voltage, and the second light characteristic is generated during the first time period using the second pixels, in response to the second test voltage. The method includes receiving an adjusted second light characteristic of the second pixels. The adjusted second light characteristic is generated during a second time period, in response to the adjusted second test voltage. The method includes re-adjusting the adjusted second test voltage, based on a third light characteristic and a fourth light characteristic, when a difference between the adjusted second light characteristic and the first light characteristic exceeds a reference value. The third light characteristic is generated during a third time period using the first pixels, in response to the first test voltage, and the fourth light characteristic is generated during the third time period using the second pixels, in response to the adjusted second test voltage.

In embodiments, the method may include storing the adjusted second test voltage in the display device when the difference between the adjusted second light characteristic and the first light characteristic is less than or equal to the reference value.

In embodiments, the adjusting the second test voltage based on the first light characteristic and the second light characteristic may include measuring light emitted from the first pixels during the first time period, in response to the first test voltage, to generate the first light characteristic. The adjusting the second test voltage based on the first light characteristic and the second light characteristic may include measuring light emitted from the second pixels during the first time period, in response to the second test voltage, to generate the second light characteristic. The adjusting the second test voltage based on the first light characteristic and the second light characteristic may include adjusting the second test voltage so that a difference between the first light characteristic and the second light characteristic is less than or equal to the reference value. The first light characteristic and the second light characteristic may be generated during the first time period.

In embodiments, the receiving the adjusted second light characteristic may include measuring the adjusted second light characteristic of the light emitted from the second pixels during the second time period, in response to the adjusted second test voltage.

In embodiments, the re-adjusting the adjusted second test voltage, based on the third light characteristic and the fourth light characteristic may include measuring the light emitted from the first pixels during the third time period, in response to the first test voltage, to generate the third light characteristic during the third time period. The re-adjusting the adjusted second test voltage, based on the third light characteristic and the fourth light characteristic may include measuring the light emitted from the second pixels during the third time period, in response to the adjusted second test voltage, to generate the fourth light characteristic, and re-adjusting the adjusted second test voltage so that a difference between the third light characteristic and the fourth light characteristic is less than or equal to the reference value during the third time period.

In embodiments, the difference between the third light characteristic and the first light characteristic may include a difference in a luminance or a difference in a color coordinate of the light emitted from the first pixels over time from the first time period to the third time period.

In embodiments, the first light characteristic may be the luminance or the color coordinate of the light emitted from the first pixels during the first time period, in response to the first test voltage. The second light characteristic may be the luminance or the color coordinate of the light emitted from the second pixels during the first time period, in response to the second test voltage. The third light characteristic may be the luminance or the color coordinate of the light emitted from the first pixels during the third time period after the first time period, in response to the first test voltage, and the fourth light characteristic may be the luminance or the color coordinate of the light emitted from the second pixels during the third time period, in response to the adjusted second test voltage.

### BRIEF DESCRIPTION OF THE DRAWINGS

The above and other features of the disclosure will become more apparent from the following description of the embodiments, taken in conjunction with the accompanying drawings, in which:

FIG. 1 is a plan view illustrating a display device according to embodiments of the disclosure;

FIG. 2 is a plan view illustrating an embodiment of a portion of a pixel unit of the display device of FIG. 1;

FIG. 3 is a circuit diagram schematically illustrating a configuration of a display device according to an embodiment of the disclosure;

FIG. 4 is a block diagram schematically illustrating a configuration of an optical compensation system according to an embodiment;

FIG. 5 is a flowchart illustrating a method of operating a test driver of FIG. 4;

FIG. 6 is a flowchart illustrating a method of operating the optical compensation device of FIG. 4;

FIG. 7 is a block diagram schematically illustrating a configuration of an optical compensation system according to an embodiment;

FIG. 8 is a flowchart illustrating a method of operating a test driver of FIG. 7;

FIG. 9 is a flowchart illustrating a method of operating the optical compensation device of FIG. 7;

FIG. 10 is a block diagram illustrating an electronic device according to embodiments of the disclosure; and

FIG. 11 is a plan view illustrating an example in which the electronic device of FIG. 10 is implemented as a smartphone.

### DETAILED DESCRIPTION OF THE EMBODIMENTS

The present invention will now be described more fully hereinafter with reference to the accompanying drawings, in which preferred embodiments of the invention are shown. In the following description, portions necessary for understanding an operation according to the disclosure may be described, and descriptions of other portions may be omitted. In addition, the disclosure may be embodied in other forms without being limited to the embodiments described herein. The embodiments described herein are provided so that this disclosure will be thorough and complete, and will fully convey the scope of the invention to those skilled in the art.

Throughout the specification, in embodiments where a portion is “connected” to another portion, the portion may be “directly connected” but also may be “indirectly connected” with another element interposed therebetween. Terms used herein are for describing specific embodiments and are not necessarily intended to limit the disclosure. Throughout the specification, in embodiments where a certain portion “includes” a component or element, the portion may further include another component, without excluding other components, unless otherwise stated. For example, “at least any of X, Y, and Z” and “at least any selected from a group consisting of X, Y, and Z” may be interpreted as one X, one Y, one Z, or any combination of two or more of X, Y, and Z (for example, XYZ, XYY, YZ, and ZZ). In an embodiment, “and/or” includes all combinations of one or more of corresponding configurations.

In an embodiment, terms such as first and second may be used to describe various components, but these components are not necessarily limited to these terms. These terms are used to distinguish one component from another component. Therefore, a first component may refer to a second component within a range, without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of “on” and “under”. In an embodiment, the device may face in other directions, for example, rotated 90 degrees, or rotated in other directions. Thus, the spatially relative terms used herein are interpreted accordingly thereto.

Various embodiments are described with reference to drawings schematically illustrating some embodiments. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Traditionally, display devices have a first pixel area and a second pixel area. However, the light characteristic of the first pixel area may be different from the light characteristic of the second pixel area. For example, the light characteristic of the pixel area surrounding a camera may be different than the light characteristic of another pixel area.

To resolve these challenges, an optical compensation device may be used. For example, an optical compensation device may be used during manufacturing of a display device. The optical compensation device may periodically generate the light characteristic of one pixel area and the light characteristic of another pixel area. The light characteristics may be generated in response to test voltages. During manufacturing, test voltage supplied to a pixel area may be adjusted until the difference between the light characteristic of one area and the light characteristic of another area is within a reference value.

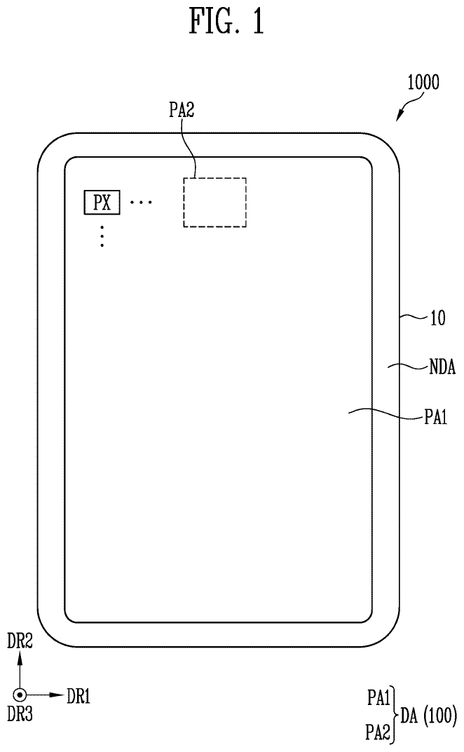

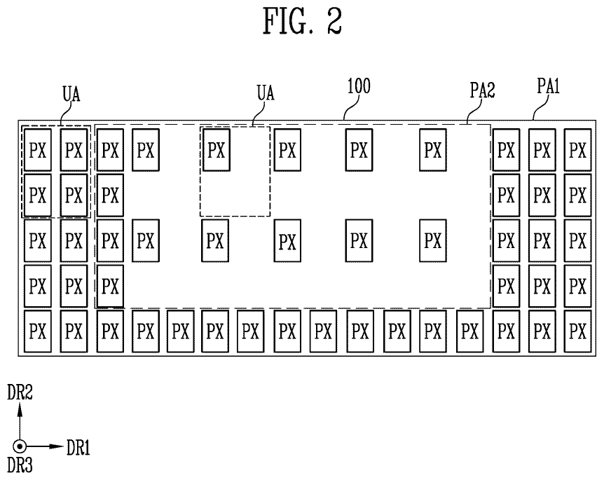

FIG. 1 is a plan view illustrating a display device according to embodiments of the disclosure. FIG. 2 is a plan view illustrating an embodiment of a portion of a pixel unit of the display device of FIG. 1.

Referring to FIGS. 1 and 2, the display device 1000 may include a display panel 10. The display panel 10 may include the pixel unit 100.

The display panel 10 may include a display area DA and a non-display area NDA. Pixels PX may be located in the display area DA, and various drivers for driving the pixels PX may be located in the non-display area NDA. The pixels PX may be located spaced apart in a first direction DR1, and may be spaced apart in a second direction DR2, crossing the first direction DR1.

The display area DA may correspond to the pixel unit 100 including a plurality of pixels PX. The pixel unit 100 may include a first pixel area PA1 and a second pixel area PA2.

In an embodiment, as shown in FIG. 2, the number (or density) of pixels PX located per unit area UA may be different in the first pixel area PA1 and the second pixel area PA2. The number (or density) of pixels PX located per unit area UA may be greater in the first pixel area PA1 than in the second pixel area PA2. For example, in the second pixel area PA2, one pixel PX may be located per unit area UA. In the first pixel area PA1, four pixels PX may be located per unit area UA. Therefore, the resolution of the second pixel area PA2 may be lower than the resolution of the first pixel area PA1.

In an embodiment, because an aperture ratio of the second pixel area PA2 is higher than an aperture ratio of the first pixel area PA1, a camera, a light sensor, or the like may overlap the second pixel area PA2. The light sensor may include a biometric information sensor such as a fingerprint sensor, an iris recognition sensor, an artery sensor, or the like. In some embodiments, for example, a light sensor may include a gesture sensor, a motion sensor, a proximity sensor, an illuminance sensor, an image sensor, or the like.

The number (or density) of pixels PX located per unit area UA in the first pixel area PA1 and the second pixel area PA2 may be different. For example, the number (or density) of pixels PX of the first pixel area PA1 may be greater than the number (or density) of pixels PX of the second pixel area PA2.

In some embodiments, a luminance of the first pixel area PA1 may be greater, provided that a same (or substantially a same) data signal is supplied to each of the pixels PX of the first pixel area PA1 and the second pixel area PA2. In some embodiments, a boundary between the first pixel area PA1 and the second pixel area PA2 may be visible to the user. For example, the user may be able to see the boundary between the first pixel area PA1 and the second pixel area PA2.

In the display device 1000, according to embodiments of the disclosure, each of the pixels PX may emit light with a grayscale of 0 to 511. However, in a driving process of the display device 1000, a grayscale range of light emitted from the pixels PX of the first pixel area PA1 and the pixels PX of the second pixel area PA2 may be different.

The number of pixels PX of the first pixel area PA1 and the second pixel area PA2 may be different. However, in the driving process of the display device 1000, each of the pixels PX of the first pixel area PA1 may emit light with a higher luminance. Therefore, the first pixel area PA1 and the second pixel area PA2 may have a same (or substantially a same) luminance. In some embodiments, visibility of the boundary between the first pixel area PA1 and the second pixel area PA2 may be alleviated.

Hereinafter, a method of optically compensating the pixels PX of the first pixel area PA1 and the second pixel area PA2, during a manufacturing process of the display device 1000, is described in detail.

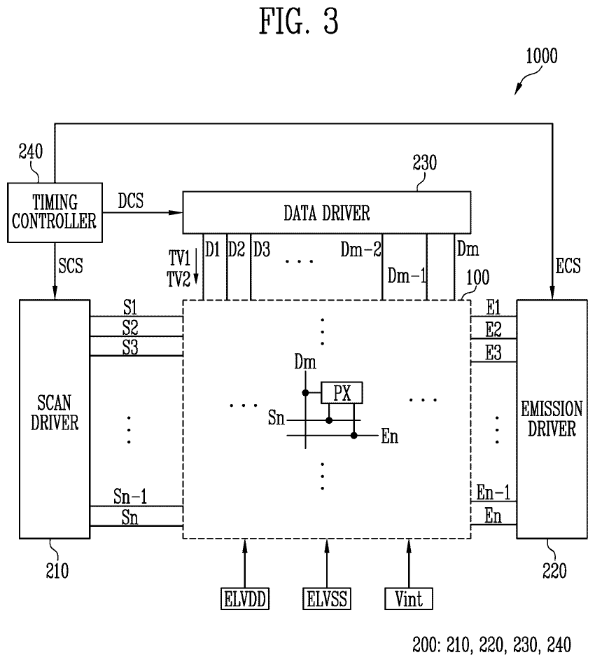

FIG. 3 is a drawing schematically illustrating a configuration of a display device according to an embodiment of the disclosure.

Referring to FIG. 3, the display device 10, according to an embodiment of the disclosure, may include a pixel unit 100 and a display driver 200. The display driver 200 may include a scan driver 210, an emission driver 220, a data driver 230, and a timing controller 240.

The timing controller 240 may generate a scan driving control signal SCS, a data driving control signal DCS, and an emission driving control signal ECS based on signals input from a processor, for example, a graphic processing unit (GPU) or the like. The scan driving control signal SCS generated by the timing controller 240 is supplied to the scan driver 210, the data driving control signal DCS is supplied to the data driver 230, and the emission driving control signal ECS is supplied to the emission driver 220.

The scan driver 210 may supply a scan signal to scan lines S1 to Sn. Here, “n” is a positive integer. In an embodiment, the scan signal(s) may correspond to the scan driving control signal SCS. For example, the scan driver 210 may sequentially supply the scan signal to the scan lines S1 to Sn.

The pixels PX may be selected in a horizontal line unit in embodiments where the scan signal is sequentially supplied to the scan lines S1 to Sn. In an embodiment, the scan signal may be set to a gate-on voltage so that a transistor included in the pixels PX may be turned on.

The data driver 230 may generate data voltages. In an optical compensation step, data voltages may include a first test voltage TV1 or a second test voltage TV2. In an optical compensation step, data voltages may include a first test voltage TV1 and a second test voltage TV2. The data driver 230 may supply the data voltages (the first test voltages TV1, the second test voltages TV2, or the like) to the data lines D1 to Dm. Here, “m” is a positive integer. In an embodiment, the data voltages may correspond to the data driving control signal DCS. The data voltages (for example, the first test voltages TV1, the second test voltages TV2, or the like) supplied to the data lines D1 to Dm may be supplied to the pixels PX selected by the scan signal.

The emission driver 220 may supply an emission control signal to emission control lines E1 to En. Here, “n” is a positive integer. In an embodiment, an emission control signal may correspond to the emission driving control signal ECS. For example, the emission driver 220 may sequentially supply the emission control signal to the emission control lines E1 to En.

The pixels PX might not emit light in the horizontal line unit, in an embodiment where the emission control signal is sequentially supplied to the emission control lines E1 to En. In an embodiment, the emission control signal is set to a gate-off voltage (for example, a high level of voltage) so that a transistor included in the pixels PX may be turned off.

In FIG. 3, the scan driver 210 and the emission driver 220 are shown as separate components, but embodiments of the disclosure are not necessarily limited thereto. For example, the scan driver 210 and the emission driver 220 may be formed as one driver.

In an embodiment, the scan driver 210 and/or the emission driver 220 may be mounted on a substrate through a thin film process.

In an embodiment, the scan driver 210 and/or the emission driver 220 may each be positioned on respective side with the pixel unit 100 interposed between the scan driver 210 and the emission driver 220.

The pixel unit 100 may include the plurality of pixels PX connected to the data lines D1 to Dm, the scan lines S1 to Sn, and the emission control lines E1 to En.

In some embodiments, the pixels PX may be supplied with initialization power Vint, first power ELVDD, and second power ELVSS from an external source. For example, the pixels PX may be supplied with initialization power Vint, first power ELVDD, and second power ELVSS using an external power supply.

Each of the pixels PX may be supplied with a scan signal through scan lines S1 to Sn connected to the pixel PX. In an embodiment, each of the pixels PX may be supplied with the data voltage through the data lines D1 to Dm. The pixel PX supplied with the data voltage may control the amount of current flowing from the first power ELVDD to the second power ELVSS via an organic light emitting diode. In an embodiment, the amount of current may correspond to the data voltage. For example, a higher data voltage would correspond to a higher current.

In an embodiment, the organic light emitting diode may generate light of a predetermined luminance, corresponding to the amount of current. In an embodiment, the first power ELVDD may be set to a voltage higher than a voltage of the second power ELVSS.

In FIG. 3, the pixel PX is shown as being connected to one scan line Sn, one data line Dm, and one emission control line En, but embodiments of the disclosure are not necessarily limited thereto. For example, the number of scan lines S1 to Sn connected to the pixel PX may be plural and the number of emission control lines E1 to En connected to the pixel PX may be plural, corresponding to a circuit structure of the pixel PX.

In some embodiments, the pixel PX may be connected only to the scan lines S1 to Sn and the data lines D1 to Dm. For example, the emission control lines E1 to En and the emission driver 220 for driving the emission control lines E1 to En may be removed.

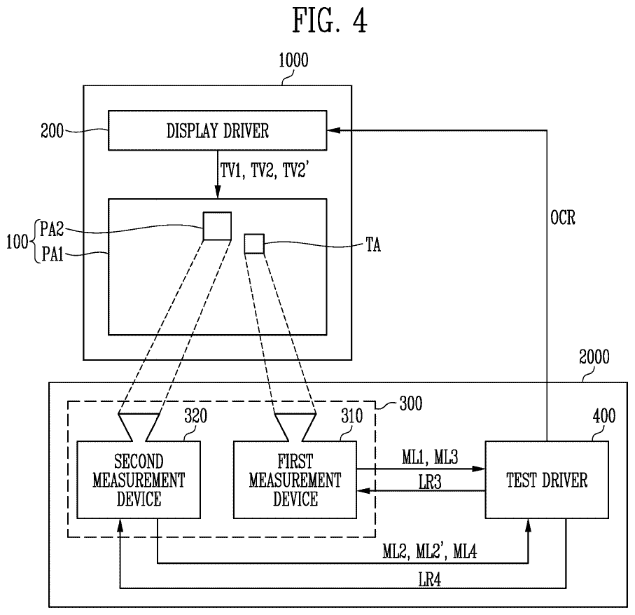

FIG. 4 is a block diagram schematically illustrating a configuration of an optical compensation system according to an embodiment.

The optical compensation system may include a display device 1000 and an optical compensation device 2000. The display device 1000 may correspond to the display device 1000 of FIG. 1 and the display device 1000 of FIG. 3. To the extent that an element is not described in detail with respect to this figure, it may be understood that the element is at least similar to a corresponding element that has been described elsewhere within the present disclosure.

In the manufacturing process of the display device 1000, optical compensation of the display device 1000 may be performed by the optical compensation device 2000. The optical compensation device 2000 may include a sensor 300 and a test driver 400. In an embodiment, a test driver 400 may include a test driver circuit.

The sensor 300 may measure light emitted from the pixel unit 100 to generate a light characteristic. The light characteristic may include a luminance and a color coordinate. In an embodiment, the light characteristic may include a luminance or a color coordinate

The sensor 300 may include a first measurement device 310 and a second measurement device 320. In an embodiment, a first measurement device may include a first sensor, and the second measurement device may include a second sensor. The first measurement device 310 may measure light emitted from first pixels of the first pixel area PA1 during a first time period, in response to a first test voltage TV1, to generate a first light characteristic ML1. In an embodiment, the first measurement device 310 may measure light emitted from first pixels of the first pixel area PA1 during a first time period. In an embodiment, the first measurement device 310 may measure light emitted from first pixels of the first pixel area PA1, in response to a first test voltage TV1. In an embodiment, the first measurement device 310 may measure light emitted from first pixels of the first pixel area PA1 to generate a first light characteristic ML1.

In an embodiment, the first measurement device 310 may measure the light emitted from the first pixels of the first pixel area PA1 during a second time period, in response to the first test voltage TV1, to generate a third light characteristic ML3. The second time period may be after the first time period.

In some embodiments, the first measurement device 310 may measure light emitted from a target area TA adjacent to the second pixel area PA2 of the first pixel area PA1, to generate the first light characteristic ML1 and the third light characteristic ML3. The first measurement device 310 may output the first light characteristic ML1 and the third light characteristic ML3 to the test driver 400. In FIG. 4, the target area TA is shown in a quadrangular shape, but the disclosure is not necessarily limited thereto and may be implemented in various shapes and forms.

The second measurement device 320 may measure light emitted from second pixels of the second pixel area PA2 during the first time period, in response to a second test voltage TV2, to generate a second light characteristic ML2. In FIG. 4, the second pixel area PA2 is shown in a quadrangular shape, but the disclosure is not necessarily limited thereto and may be implemented in various shapes and forms.

In some embodiments, the second measurement device 320 may measure the light emitted from the second pixels of the second pixel area PA2 during a third time period, in response to an adjusted second test voltage TV2′, to generate an adjusted second light characteristic ML2′. In an embodiment, an adjusted test voltage may refer to, or include, a corrected test voltage. For example, an adjusted second test voltage TV2′ may refer to, or include, a corrected second test voltage TV2′. In an embodiment, an adjusted light characteristic may refer to, or include, a corrected light characteristic. For example, an adjusted second light characteristic ML2′ may refer to, or include, a corrected second light characteristic ML2′. The second measurement device 320 may output the second light characteristic ML2 and the adjusted second light characteristic ML2′ to the test driver 400.

The test driver 400 may output an optical compensation request OCR to the display driver 200. The optical compensation request OCR may include the first test voltage TV1 and the second test voltage TV2. The first test voltage TV1 and the second test voltage TV2 may be determined for each grayscale or maximum luminance. The maximum luminance may be a luminance of light emitted from pixels set to a maximum grayscale, for example, 255 grayscales in embodiments where grayscales are expressed in 8 bits. The test driver 400 may set the first test voltage TV1 and the second test voltage TV2. The first test voltage TV1 and the second test voltage TV2 may correspond to each of various grayscales or each of various maximum luminances.

The display driver 200 may output the first test voltage TV1 to the first pixel area PA1 and output the second test voltage TV2 to the second pixel area PA2, in response to the optical compensation request.

The test driver 400 may adjust the second test voltage TV2 based on the first light characteristic ML1 and the second light characteristic ML2. The test driver 400 may adjust the second test voltage TV2 so that the second light characteristic ML2 becomes similar to the first light characteristic ML1. In some embodiments, the test driver 400 may adjust the second test voltage TV2 so that a difference between the first light characteristic ML1 and the second light characteristic ML2 is less than or equal to a reference value. The reference value may be a predetermined value.

The test driver 400 may output the adjusted second test voltage TV2′ to the display driver 200. The second measurement device 320 may measure the light emitted from the second pixels of the second pixel area PA2 during the third time period, in response to the adjusted second test voltage TV2′, to generate the adjusted second light characteristic ML2′. The third time period may be between the first time period and the second time period.

The test driver 400 may output a third light characteristic generation request LR3 to the first measurement device 310 and output a fourth light characteristic generation request LR4 to the second measurement device 320, in an embodiment where a difference between the adjusted second light characteristic ML2′ and the first light characteristic ML1 is greater than or equal to the reference value.

The test driver 400 may store the adjusted second test voltage TV2′ in the display driver 200, in an embodiment where the difference between the adjusted second light characteristic ML2′ and the first light characteristic ML1 is less than the reference value.

For example, the adjusted second test voltages TV2′ for each grayscale may be stored in a form of a data voltage for each grayscale. For example, the adjusted second test voltages TV2′ for each maximum luminance may be stored in a form of a data voltage for each maximum luminance.

The first measurement device 310 may measure the light emitted from the first pixels of the target area TA during the second time period, in response to the third light characteristic generation request, to generate the third light characteristic ML3. A difference between the third light characteristic ML3 and the first light characteristic ML1 may include a difference in amount of luminance or difference in color coordinate of the light emitted from the first pixels of the target area TA according to passage of time, for example, over time from the first time period to the second time period.

The second measurement device 320 may measure the light emitted from the second pixel area PA2 during the second time period, in response to the fourth light characteristic generation request, to generate a fourth light characteristic ML4.

The test driver 400 may re-adjust the adjusted second test voltage TV2′, based on the third light characteristic ML3 and the fourth light characteristic ML4. The test driver 400 may re-adjust the adjusted second test voltage TV2′ so that the fourth light characteristic ML4 becomes similar to the third light characteristic ML3. In some embodiments, the test driver 400 may adjust the adjusted second test voltage TV2′ so that a difference between the third light characteristic ML3 and the fourth light characteristic ML4 is less than or equal to the reference value.

In the pixel unit 100 of the display device 1000, a phenomenon according to which a color coordinate of a displayed image, particularly a luminance or a color coordinate of a low-grayscale image, may change with the passage of a driving time, may occur. The phenomenon may be referred to as a change with time phenomenon.

Reasonably accurate optical compensation may be performed as the test driver 400 adjusts the fourth light characteristic ML4 based on the third light characteristic ML3, reflecting the change of the luminance or the color coordinate according to the change with time phenomenon.

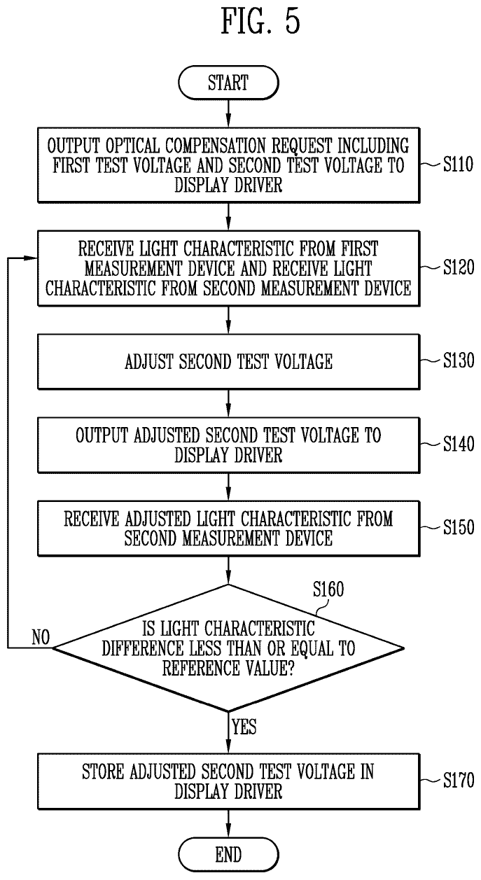

FIG. 5 is a flowchart illustrating a method of operating the test driver of FIG. 4. Referring to FIGS. 4 and 5, the test driver 400 may again receive a light characteristic from the first measurement device 310, in an embodiment where a difference between the first light characteristic ML1 and the adjusted second light characteristic ML2′ deviates from the reference value.

In step S110, the test driver 400 may output the optical compensation request to the display driver 200. The optical compensation request may include the first test voltage TV1 and the second test voltage TV2.

In step S120, the test driver 400 may receive the first light characteristic ML1 generated during the first time period from the first measurement device 310, and may receive the second light characteristic ML2 generated during the first time period from the second measurement device 320.

In step S130, the test driver 400 may adjust the second test voltage TV2 so that the light characteristic received from the second measurement device 320 becomes similar to the light characteristic received from the first measurement device 310.

In step S140, the test driver 400 may output the adjusted second test voltage TV2′ to the display driver 200.

In step S150, the test driver 400 may receive the adjusted second light characteristic ML2′ from the second measurement device 320.

In step S160, the test driver 400 may compare whether a light characteristic difference is less than or equal to the reference value. The light characteristic difference may be the difference between the first light characteristic ML1 received from the first measurement device 310 and the adjusted second light characteristic ML2′ received from the second measurement device 320.

The test driver 400 may perform step S170, in an embodiment where the light characteristic difference is less than or equal to the reference value. In step S170, the test driver 400 may store the adjusted second test voltage TV2′ in the display driver 200.

Step S120 may be performed in an embodiment where the light characteristic difference is greater than the reference value. The test driver 400 may receive the third light characteristic ML3 generated from the target area TA, during the second time period, from the first measurement device 310, and may receive the fourth light characteristic ML4 generated from the second pixel area PA2, during the second time period, from the second measurement device 320. Thereafter, steps S130 to S160 may be repeated until the light characteristic difference is less than or equal to the reference value.

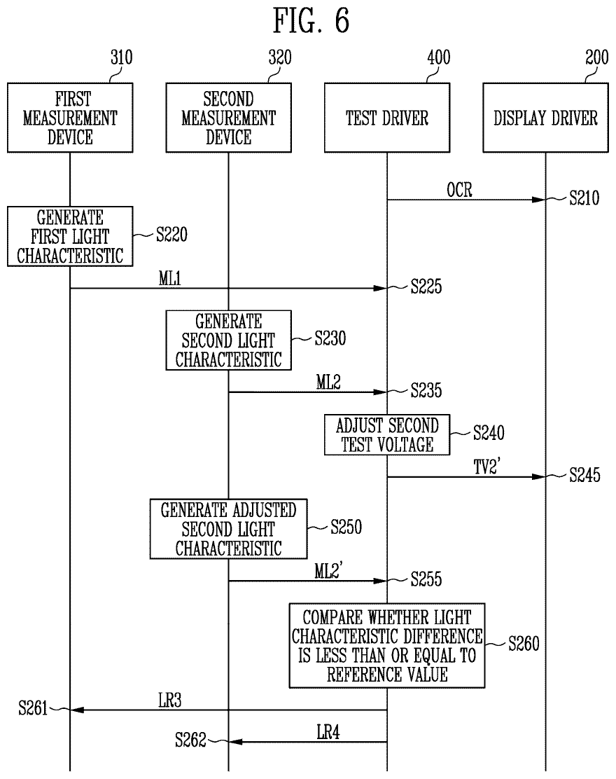

FIG. 6 is a flowchart illustrating a method of operating the optical compensation device of FIG. 4.

Referring to FIGS. 4 and 6, the test driver 400 may again receive the light characteristic from the first measurement device 310, in an embodiment where the difference between the first light characteristic ML1 and the adjusted second light characteristic ML2′ is greater than the reference value.

In step S210, the test driver 400 may output an optical compensation request OCR to the display driver 200. The display driver 200 may apply the first test voltage TV1 to the target area TA and may apply the second test voltage TV2 to the second pixel area PA2, in response to the optical compensation request OCR.

In step S220, the first measurement device 310 may measure the light emitted from the first pixels PXL1 of the target area TA, in response to the first test voltage TV1, to generate the first light characteristic ML1.

In step S225, the first measurement device 310 may output the first light characteristic ML1 to the test driver 400.

In step S230, the second measurement device 320 may measure the light emitted from the second pixels PXL2 of the second pixel area PA2, in response to the second test voltage TV2, to generate the second light characteristic ML2.

In step S235, the second measurement device 320 may output the second light characteristic ML2 to the test driver 400.

In FIG. 6, steps S220, S225, S230, and S235 are shown as being performed in order, but the disclosure is not necessarily limited thereto. According to some embodiments, steps S220 and S230 may be performed simultaneously, and steps S225 and S235 may be performed simultaneously after steps S220 and S230 were performed simultaneously.

In step S240, the test driver 400 may adjust the second test voltage TV2, based on the first light characteristic ML1 and the second light characteristic ML2.

In step S245, the test driver 400 may output the adjusted second test voltage TV2′ to the display driver 200. The display driver 200 may apply the adjusted second test voltage TV2′ to the second pixel area PA2.

In step S250, the second measurement device 320 may measure the light emitted from the second pixels PXL2 of the second pixel area PA2, in response to the adjusted second test voltage TV2′, to generate the adjusted second light characteristic ML2′.

In step S255, the second measurement device 320 may output the adjusted second light characteristic ML2′ to the test driver 400.

In step S260, the test driver 400 may compare the difference between the first light characteristic ML1 and the adjusted second light characteristic ML2′ with the reference value.

The test driver 400 may perform steps S261 and S262 in an embodiment where the difference between the first light characteristic ML1 and the adjusted second light characteristic ML2′ is greater than or equal to the reference value.

In step S261, the test driver 400 may output a third light characteristic generation request LR3 to the first measurement device 310. In response to the third light characteristic generation request LR3, the first measurement device 310 may measure the light emitted from the first pixels PXL1 of the target area TA, in response to the first test voltage TV1, to generate the third light characteristic ML3.

In step S262, the test driver 400 may output a fourth light characteristic generation request LR4 to the second measurement device 320. In response to the fourth light characteristic generation request LR4, the second measurement device 320 may measure the light emitted from the second pixels PXL2 of the second pixel area PA2, in response to the adjusted second test voltage TV2′, to generate the fourth light characteristic ML4.

Thereafter, the test driver 400 may re-adjust the adjusted second test voltage TV2′, based on the third light characteristic ML3 and the fourth light characteristic ML4.

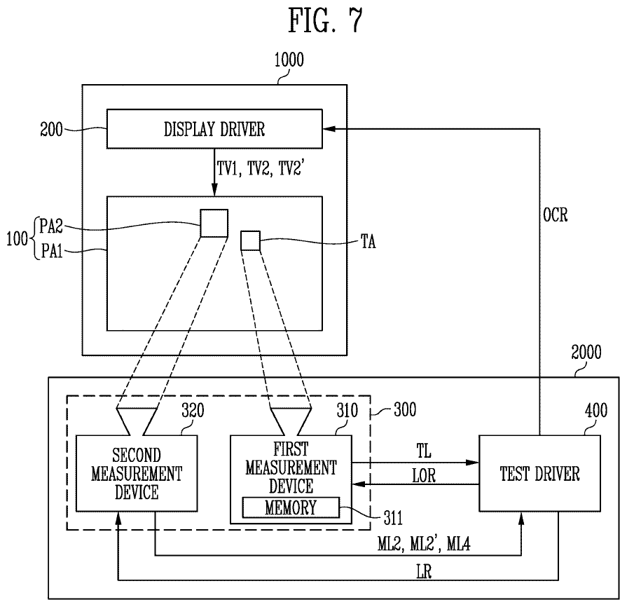

FIG. 7 is a block diagram schematically illustrating a configuration of an optical compensation system according to an embodiment.

The optical compensation system may include a display device 1000 and an optical compensation device 2000. The display device 1000 may correspond to the display device 1000 of FIG. 4. To the extent that an element is not described in detail with respect to this figure, it may be understood that the element is at least similar to a corresponding element that has been described elsewhere within the present disclosure.

In the manufacturing process of the display device 1000, optical compensation of the display device 1000 may be performed by the optical compensation device 2000. The optical compensation device 2000 may include a sensor 300 and a test driver 400. The optical compensation device 2000 may correspond to the optical compensation device 2000 of FIG. 4. To the extent that an element is not described in detail with respect to this figure, it may be understood that the element is at least similar to a corresponding element that has been described elsewhere within the present disclosure.

The sensor 300 may measure the light emitted from the pixel unit 100 to generate the light characteristic. The light characteristic may include the luminance and/or the color coordinate.

The sensor 300 may include the first measurement device 310 and the second measurement device 320. The first measurement device 310 may periodically measure the light emitted from first pixels of the first pixel area PA1, in response to the first test voltage TV1, to generate the first light characteristic. A period at which the first measurement device 310 generates the first light characteristic may be determined by a user of the optical compensation device 2000.

In embodiments, the first measurement device 310 may measure the light emitted from the target area TA of the first pixel area PA1 to generate the first light characteristic. In an embodiment, the target area TA may be adjacent to the second pixel area PA2.

The first measurement device 310 may include a memory 311. The first measurement device 310 may store a most recently generated first light characteristic as a target light characteristic TL in the memory 311. For example, the target light characteristic TL stored in the memory 311 may be the first light characteristic ML1 most recently generated by the first measurement device 310. The first measurement device 310 may output the target light characteristic TL stored in the memory 311 to the test driver 400.

The second measurement device 320 may measure the light emitted from the second pixels of the second pixel area PA2, in response to the second test voltage TV2, to generate the second light characteristic ML2.

In some embodiments, the second measurement device 320 may measure the light emitted from the second pixels of the second pixel area PA2, in response to the adjusted second test voltage TV2′, to generate the adjusted second light characteristic ML2′. The second measurement device 320 may output the second light characteristic ML2 and the adjusted second light characteristic ML2′ to the test driver 400.

The test driver 400 may output the optical compensation request OCR to the display driver 200. The optical compensation request OCR may include the first test voltage TV1 and the second test voltage TV2.

The display driver 200 may output the first test voltage TV1 to the target area TA and may output the second test voltage TV2 to the second pixel area PA2, in response to the optical compensation request OCR.

The test driver 400 may adjust the second test voltage TV2, based on the target light characteristic TL and the second light characteristic ML2. The test driver 400 may adjust the second test voltage TV2 so that the second light characteristic ML2 becomes similar to the target light characteristic TL. In embodiments, the test driver 400 may adjust the second test voltage TV2 so that a difference between the target light characteristic TL and the second light characteristic ML2 is less than or equal to a reference value. The reference value may be a predetermined value.

The test driver 400 may output the adjusted second test voltage TV2′ to the display driver 200. The second measurement device 320 may measure the light emitted from the second pixels of the second pixel area PA2, in response to the adjusted second test voltage TV2,′ to generate the adjusted second light characteristic ML2′.

The test driver 400 may output a light transmission request LOR to the first measurement device 310 and may output a light characteristic generation request LR to the second measurement device 320 in an embodiment where a difference between the adjusted second light characteristic ML2′ and the target light characteristic TL is greater than or equal to the reference value.

The test driver 400 may store the adjusted second test voltage TV2′ in the display driver 200, in an embodiment where the difference between the adjusted second light characteristic ML2′ and the first light characteristic ML1 is less than the reference value.

For example, the adjusted second test voltages TV2′ for each grayscale may be stored in the form of the data voltage for each grayscale. For example, the adjusted second test voltages TV2′ for each maximum luminance may be stored in the form of the data voltage for each maximum luminance.

The first measurement device 310 may output the target light characteristic TL stored in the memory 311 to the test driver 400, in response to the light transmission request LOR. A difference between the target light characteristic TL stored in the memory 311 before receiving the light transmission request LOR and the target light characteristic TL stored in the memory 311 after receiving the light transmission request LOR may include the difference in the luminance or difference in the color coordinate of the light emitted from the first pixels of the target area TA, according to passage of time, or over time.

The second measurement device 320 may measure the light emitted from the second pixel area PA2, in response to the light characteristic generation request LR, to generate the fourth light characteristic ML4.

The test driver 400 may re-adjust the adjusted second test voltage TV2′, based on the target light characteristic TL and the fourth light characteristic ML4. The test driver 400 may re-adjust the adjusted second test voltage TV2′ so that the fourth light characteristic ML4 becomes similar to the target light characteristic TL. In embodiments, the test driver 400 may adjust the adjusted second test voltage TV2′ so that a difference between the target light characteristic TL and the fourth light characteristic ML4 is less than or equal to the reference value.

Reasonably accurate optical compensation may be performed as the test driver 400 adjusts the fourth light characteristic ML4 based on the target light characteristic TL, the adjustment reflecting a change of the luminance or the color coordinate according to a change with time phenomenon described in more detail above.

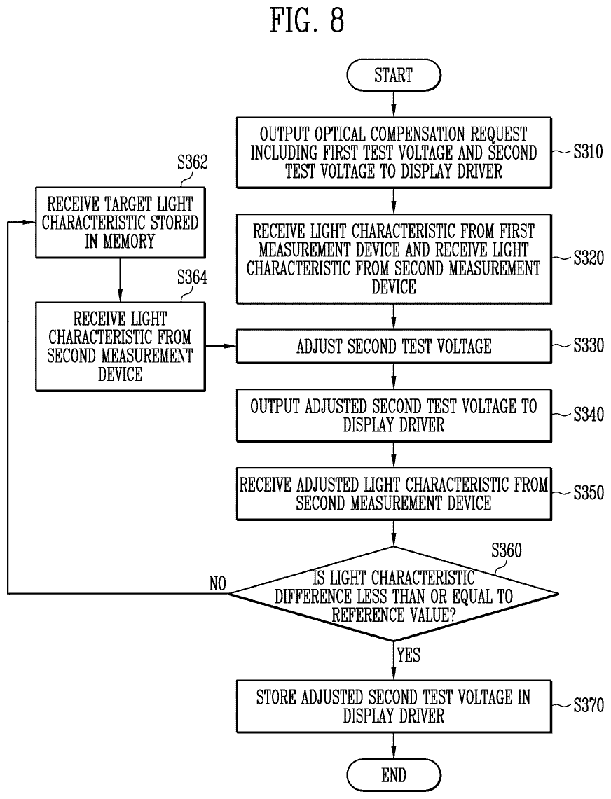

FIG. 8 is a flowchart illustrating a method of operating the test driver of FIG. 7. Referring to FIGS. 7 and 8, the test driver 400 may receive the light characteristic again from the first measurement device 310, in an embodiment where the difference between the target light characteristic TL and the adjusted second light characteristic ML2′ deviates from the reference value.

In step S310, the test driver 400 may output the optical compensation request to the display driver 200. The optical compensation request may include the first test voltage TV1 and the second test voltage TV2.

In step S320, the test driver 400 may receive the target light characteristic TL from the first measurement device 310 and may receive the second light characteristic ML2 from the second measurement device 320.

In step S330, the test driver 400 may adjust the second test voltage TV2 so that the light characteristic received from the second measurement device 320 becomes similar to the light characteristic received from the first measurement device 310.

In step S340, the test driver 400 may output the adjusted second test voltage TV2′ to the display driver 200.

In step S350, the test driver 400 may receive the adjusted second light characteristic ML2′ from the second measurement device 320.

In step S360, the test driver 400 may compare whether a light characteristic difference is less than or equal to the reference value. For example, the light characteristic difference may be the difference between the target light characteristic TL received from the first measurement device 310 and the adjusted second light characteristic ML2′ received from the second measurement device 320.

The test driver 400 may perform step S370 in an embodiment where the light characteristic difference is less than or equal to the reference value. In step S370, the test driver 400 may store the adjusted second test voltage TV2′ in the display driver 200.

Step S362 may be performed in an embodiment where the light characteristic difference is greater than the reference value.

In step S362, the test driver 400 may receive the target light characteristic TL stored in the memory 311 from the first measurement device 310.

In step S364, the test driver 400 may receive the fourth light characteristic ML4 generated from the second pixel area PA2 from the second measurement device 320. Thereafter, steps S330, S340, S350, S360, S362, and S364 may be repeated until the light characteristic difference is less than or equal to the reference value.

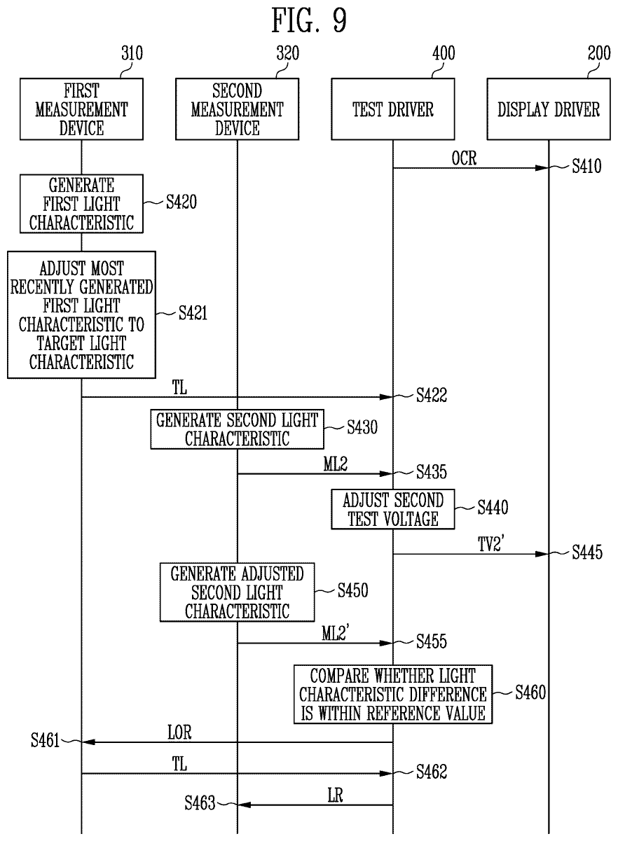

FIG. 9 is a flowchart illustrating a method of operating the optical compensation device of FIG. 7.

Referring to FIGS. 7 and 9, the test driver 400 may receive the light characteristic again from the first measurement device 310 in an embodiment where the difference between the target light characteristic TL and the adjusted second light characteristic ML2′ is greater than the reference value.

In step S410, the test driver 400 may output the optical compensation request OCR to the display driver 200. In response to the optical compensation request OCR, the display driver 200 may apply the first test voltage TV1 to the target area TA and may apply the second test voltage TV2 to the second pixel area PA2.

In step S420, the first measurement device 310 may measure the light emitted from the first pixels PXL1 of the target area TA, in response to the first test voltage TV1, to generate the first light characteristic ML1.

In step S421, the first measurement device 310 may adjust a most recently generated first light characteristic ML1 to the target light characteristic TL stored in the memory 311.

In step S422, the first measurement device 310 may output the target light characteristic TL to the test driver 400.

In step S430, the second measurement device 320 may measure the light emitted from the second pixels PXL2 of the second pixel area PA2, in response to the second test voltage TV2, to generate the second light characteristic ML2.

In step S435, the second measurement device 320 may output the second light characteristic ML2 to the test driver 400.

In FIG. 9, steps S420, S421, S422, S430, and S435 are shown to be performed in order, but the disclosure is not necessarily limited thereto. According to embodiments, steps S420 and S430 may be performed simultaneously, and step S421 may be performed after step S435.

In step S440, the test driver 400 may adjust the second test voltage TV2, based on the target light characteristic TL and the second light characteristic ML2.

In step S445, the test driver 400 may output the adjusted second test voltage TV2′ to the display driver 200. The display driver 200 may apply the adjusted second test voltage TV2′ to the second pixel area PA2.

In step S450, the second measurement device 320 may measure the light emitted from the second pixels PXL2 of the second pixel area PA2, in response to the adjusted second test voltage TV2′, to generate the adjusted second light characteristic ML2′.

In step S455, the second measurement device 320 may output the adjusted second light characteristic ML2′ to the test driver 400.

In step S460, the test driver 400 may compare the difference between the target light characteristic TL and the adjusted second light characteristic ML2′ with the reference value.

The test driver 400 may perform steps S461, S462, and S463 in an embodiment where the difference between the target light characteristic TL and the adjusted second light characteristic ML2′ is greater than or equal to the reference value.

In step S461, the test driver 400 may output the light transmission request LOR to the first measurement device 310.

In step S462, in response to the light transmission request LOR, the first measurement device 310 may output the target light characteristic TL stored in the memory 311 to the test driver 400.

In step S463, the test driver 400 may output the light characteristic generation request LR to the second measurement device 320. In response to the light characteristic generation request LR, the second measurement device 320 may measure the light emitted from the second pixels PXL2 of the second pixel area PA2, in response to the adjusted second test voltage TV2′, to generate the fourth light characteristic ML4.

In an embodiment, the test driver 400 re-adjusts the adjusted second test voltage TV2′, based on the target light characteristic TL and the fourth light characteristic ML4.

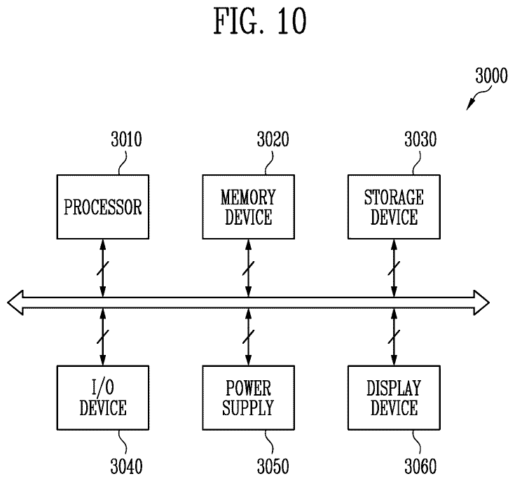

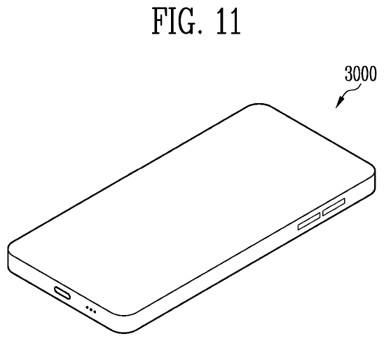

FIG. 10 is a block diagram illustrating an electronic device according to embodiments of the disclosure, and FIG. 11 is a plan view illustrating an embodiment in which the electronic device of FIG. 10 is implemented as a smartphone.

Referring to FIGS. 10 and 11, the electronic device 3000 may include a processor 3010, a memory device 3020, a storage device 3030, an input/output device 3040, a power supply 3050, and a display device 3060. In an embodiment, the display device 3060 may be the display device of FIG. 1. In an embodiment, the electronic device 3000 may further include several ports capable of communicating with a video card, a sound card, a memory card, a USB device, or the like, or communicating with other systems. In an embodiment, as shown in FIG. 11, the electronic device 3000 may be implemented as a smart phone. However, this is an example, and the electronic device 3000 is not necessarily limited thereto. For example, the electronic device 3000 may be implemented as a mobile phone, a video phone, a smart pad, a smartwatch, a tablet computer, a vehicle navigation device, a computer monitor, a notebook computer, a head mounted display device, or the like.

In an embodiment, the processor 3010 may perform specific calculations or tasks. According to an embodiment, the processor 3010 may be a microprocessor, a central processing unit, an application processor, or the like. The processor 3010 may be connected to other components through an address bus, a control bus, a data bus, or the like. According to an embodiment, the processor 3010 may also be connected to an expansion bus such as a peripheral component interconnect (PCI) bus.

The memory device 3020 may store data necessary for an operation of the electronic device 3000. For example, the memory device 3020 may include a non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), and a ferroelectric random access memory (FRAM) device, a volatile memory device such as a dynamic random access memory (DRAM) device, a static random access memory (SRAM) device, and a mobile DRAM device, and/or the like.

The storage device 3030 may include a solid-state drive (SSD), a hard disk drive (HDD), a CD-ROM, and/or the like.

The input/output device 3040 may include an input means such as a keyboard, a keypad, a touch pad, a touch screen, or a mouse, and an output means such as a speaker or a printer. According to an embodiment, the display device 3060 may be included in the input/output device 3040.

The power supply 3050 may supply power necessary for an operation of the electronic device 3000. For example, the power supply 3050 may be a power management integrated circuit (PMIC).

The display device 3060 may display an image corresponding to the visual information of the electronic device 3000. In an embodiment, the display device 3060 may be an organic light emitting display device or a quantum dot light emitting display device, but is not necessarily limited thereto. The display device 3060 may be connected to other components through the buses or other communication links.

Those skilled in the art will recognize that the present disclosure can be practiced in other specific ways without departing from its technical spirit or essential characteristics. The described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. An optical compensation device, comprising:
a first sensor configured to:
measure light emitted from a first pixel area of a display device during a first time period, in response to a first test voltage, to generate a first light characteristic, and
measure light emitted from the first pixel area during a second time period, in response to the first test voltage, to generate a third light characteristic;
a second sensor configured to measure light emitted from a second pixel area of the display device during the first time period, in response to a second test voltage, to generate a second light characteristic; and
a test driver circuit configured to adjust the second test voltage, based on the first light characteristic and the second light characteristic.

2. The optical compensation device according to claim 1, wherein:
the second sensor is configured to measure light emitted from the second pixel area during a third time period, in response to the adjusted second test voltage, to generate an adjusted second light characteristic,
the test driver circuit is configured to output a third light characteristic generation request to the first sensor and output a fourth light characteristic generation request to the second sensor, when a difference between the adjusted second light characteristic and the first light characteristic is greater than or equal to a reference value,
the first sensor is configured to generate the third light characteristic, in response to the third light characteristic generation request, and
the third time period is between the first time period and the second time period.

3. The optical compensation device according to claim 2, wherein the test driver circuit is configured to store the adjusted second test voltage in the display device, when the difference between the adjusted second light characteristic and the first light characteristic is less than or equal to the reference value.

4. The optical compensation device according to claim 2, wherein:
in response to the fourth light characteristic generation request, the second sensor is configured to measure light emitted from the second pixel area during the second time period, in response to the adjusted second test voltage, to generate a fourth light characteristic, and
the test driver circuit is configured to re-adjust the adjusted second test voltage, based on the third light characteristic and the fourth light characteristic.

5. The optical compensation device according to claim 4, wherein a difference between the third light characteristic and the first light characteristic includes a difference in a luminance or a difference in a color coordinate of the light emitted from first pixels of the first pixel area over time from the first time period to the second time period.

6. The optical compensation device according to claim 5, wherein:
the first light characteristic is the luminance or the color coordinate of the light emitted from the first pixels during the first time period, in response to the first test voltage,
the second light characteristic is the luminance or the color coordinate of the light emitted from second pixels of the second pixel area during the first time period, in response to the second test voltage,
the third light characteristic is the luminance or the color coordinate of the light emitted from the first pixels during the second time period after the first time period, in response to the first test voltage, and
the fourth light characteristic is the luminance or the color coordinate of the light emitted from the second pixels during the second time period, in response to the adjusted second test voltage.

7. The optical compensation device according to claim 6, wherein a number of the first pixels located per unit area is greater than a number of the second pixels located per unit area.

8. An electronic device, comprising:
a processor configured to generate input image data and a control signal; and
a display device configured to display an image based on the input image data and the control signal, the display device including a first pixel area including first pixels, and a second pixel area including second pixels, wherein the display device is configured to communicate with an optical compensation device,
the optical compensation device, comprising:
a first sensor configured to periodically measure light emitted from the first pixel area of the display device, in response to a first test voltage, to generate a first light characteristic, wherein a most recently generated first light characteristic is stored as a target light characteristic;
a second sensor configured to measure light emitted from the second pixel area of the display device, in response to a second test voltage, to generate a second light characteristic; and
a test driver circuit configured to adjust the second test voltage, based on the target light characteristic and the second light characteristic.

9. The electronic device according to claim 8, wherein:
the second sensor is configured to measure light emitted from the second pixel area, in response to the adjusted second test voltage, to generate an adjusted second light characteristic, and
the test driver circuit is configured to output a light characteristic generation request to the second sensor and output a light transmission request to the first sensor, when a difference between the adjusted second light characteristic and the stored first light characteristic is greater than or equal to a reference value.

10. The electronic device according to claim 9, wherein the test driver circuit is configured to store the adjusted second test voltage in the display device, when the difference between the adjusted second light characteristic and the stored first light characteristic is less than or equal to the reference value.

11. The electronic device according to claim 9, wherein:
the first sensor is configured to output the target light characteristic to the test driver circuit, in response to the light transmission request,
the second sensor is configured to measure the light emitted from the second pixel area, in response to the adjusted second test voltage, to generate a third light characteristic, wherein the third light characteristic is generated in response to the light characteristic generation request, and
the test driver circuit is configured to re-adjust the adjusted second test voltage based on the target light characteristic and the third light characteristic.

12. The electronic device according to claim 11, wherein the target light characteristic stored before receiving the light transmission request and the target light characteristic stored after receiving the light transmission request are different from each other.

13. The electronic device according to claim 12, wherein the difference between the target light characteristic stored before receiving the light transmission request and the target light characteristic stored after receiving the light transmission request includes a difference in a luminance or a difference in a color coordinate of light emitted from first pixels of the first pixel area over time.

14. A method of operating an optical compensation device configured to communicate with a display device, the display device comprising a first pixel area including first pixels, and a second pixel area including second pixels, the method, comprising:
adjusting a second test voltage based on a first light characteristic and a second light characteristic, wherein the first light characteristic is generated during a first time period using the first pixels, in response to a first test voltage, and wherein the second light characteristic is generated during the first time period using the second pixels, in response to the second test voltage;
receiving an adjusted second light characteristic of the second pixels, wherein the adjusted second light characteristic is generated during a second time period, in response to the adjusted second test voltage; and
re-adjusting the adjusted second test voltage, based on a third light characteristic and a fourth light characteristic, when a difference between the adjusted second light characteristic and the first light characteristic exceeds a reference value, wherein:
the third light characteristic is generated during a third time period using the first pixels, in response to the first test voltage, and
the fourth light characteristic is generated during the third time period using the second pixels, in response to the adjusted second test voltage.

15. The method according to claim 14, further comprising:
storing the adjusted second test voltage in the display device, when the difference between the adjusted second light characteristic and the first light characteristic is less than or equal to the reference value.

16. The method according to claim 14, wherein the adjusting the second test voltage based on the first light characteristic and the second light characteristic comprises:
measuring light emitted from the first pixels during the first time period, in response to the first test voltage, to generate the first light characteristic;
measuring light emitted from the second pixels during the first time period, in response to the second test voltage, to generate the second light characteristic; and
adjusting the second test voltage so that a difference between the first light characteristic and the second light characteristic is less than or equal to the reference value, wherein the first light characteristic and the second light characteristic are generated during the first time period.

17. The method according to claim 16, wherein the receiving the adjusted second light characteristic comprises measuring the adjusted second light characteristic of the light emitted from the second pixels during the second time period, in response to the adjusted second test voltage.

18. The method according to claim 17, wherein the re-adjusting the adjusted second test voltage, based on the third light characteristic and the fourth light characteristic comprises:
measuring the light emitted from the first pixels during the third time period, in response to the first test voltage, to generate the third light characteristic during the third time period;
measuring the light emitted from the second pixels during the third time period, in response to the adjusted second test voltage, to generate the fourth light characteristic; and
re-adjusting the adjusted second test voltage so that a difference between the third light characteristic and the fourth light characteristic is less than or equal to the reference value during the third time period.

19. The method according to claim 18, wherein the difference between the third light characteristic and the first light characteristic includes a difference in a luminance or a difference in a color coordinate of the light emitted from the first pixels over time from the first time period to the third time period.

20. The method according to claim 19, wherein:
the first light characteristic is the luminance or the color coordinate of the light emitted from the first pixels during the first time period, in response to the first test voltage,
the second light characteristic is the luminance or the color coordinate of the light emitted from the second pixels during the first time period, in response to the second test voltage,
the third light characteristic is the luminance or the color coordinate of the light emitted from the first pixels during the third time period after the first time period, in response to the first test voltage, and
the fourth light characteristic is the luminance or the color coordinate of the light emitted from the second pixels during the third time period, in response to the adjusted second test voltage.
